(19) United States
(12) Patent Application Publication
(10) Pub. No.: US 2026/0126717 A1
(43) Pub. Date: May 7, 2026

(54) PELLICLE FILM ATTACHMENT DEVICE AND PELLICLE FILM ATTACHMENT METHOD, AND PELLICLE FILM TRANSFER APPARATUS AND PELLICLE FILM TRANSFER METHOD

(71) Applicant: LINTEC Corporation, Tokyo (JP)

(72) Inventors: Marcio D. LIMA, Plano, TX (US); Takahiro UEDA, Tokyo (JP); Takumi FURUYA, Plano, TX (US); Trevor Harrison DUNCAN, Plano, TX (US)

(21) Appl. No.: 19/380,511

(22) Filed: Nov. 5, 2025

Related U.S. Application Data
(60) Provisional application No. 63/717,444, filed on Nov. 7, 2024.

(51) Int. Cl. G03F 1/64

(52) U.S. Cl. CPC G03F 1/64

(57) ABSTRACT

A pellicle film attachment device includes: an affinity improvement treatment unit configured to perform, on an adherend surface of a first frame member, an affinity improvement treatment to improve an affinity for a liquid; a liquid adhesion unit configured to cause the liquid to adhere to the adherend surface having been subjected to the affinity improvement treatment; and an attachment unit configured to attach a pellicle film to the adherend surface to which the liquid adheres.

### CROSS REFERENCE TO RELATED APPLICATIONS

The entire disclosure of U.S. Provisional Application No. 63/717,444 filed Nov. 7, 2024 is expressly incorporated by reference herein.

### TECHNICAL FIELD

The present invention relates to a pellicle film attachment device and a pellicle film attachment method, and a pellicle film transfer apparatus and a pellicle film transfer method.

### BACKGROUND ART

A pellicle film attachment device that attaches a pellicle film to an adherend surface of a frame member is known (see, for instance, Patent Literature 1: JP 2020-160345 A).

In a device described in Patent Literature 1, water (liquid) may not adhere uniformly to a portion 190A (adherend surface) of a frame-shaped member 190 (first frame member), and thus there is a concern that a carbon nanotube self-supported film 125 (pellicle film) is unevenly attached to the adherend surface of the first frame member.

### SUMMARY OF THE INVENTION

An object of the invention is to provide a pellicle film attachment device, a pellicle film attachment method, a pellicle film transfer apparatus, and a pellicle film transfer method that are capable of preventing a pellicle film from being unevenly attached to an adherend surface of a frame member.

A pellicle film attachment device according to an aspect of the invention includes: an affinity improvement treatment unit configured to perform, on an adherend surface of a first frame member, an affinity improvement treatment to improve an affinity for a liquid; a liquid adhesion unit configured to cause the liquid to adhere to the adherend surface having been subjected to the affinity improvement treatment; and an attachment unit configured to attach a pellicle film to the adherend surface to which the liquid adheres.

A pellicle film transfer apparatus according to another aspect of the invention includes: the pellicle film attachment device according to the above aspect; and a transfer unit configured to transfer the pellicle film attached to a second frame member to the first frame member.

A pellicle film attachment method according to still another aspect of the invention includes: performing, on an adherend surface of a first frame member, an affinity improvement treatment to improve an affinity for a liquid; causing the liquid to adhere to the adherend surface having been subjected to the affinity improvement treatment; and attaching a pellicle film to the adherend surface to which the liquid adheres.

A pellicle film transfer method according to a further aspect of the invention includes: the pellicle film attachment method according to the still another aspect of the invention; and transferring the pellicle film attached to a second frame member to the first frame member.

According to the above device, apparatus, and methods, the adherend surface of the first frame member is subjected to the affinity improvement treatment. The liquid thus evenly adheres to the adherend surface, which makes it possible to prevent the pellicle film from being unevenly attached to the adherend surface of the first frame member.

### BRIEF DESCRIPTION OF DRAWINGS

FIG. 1 is a front view of a pellicle film transfer apparatus according to an exemplary embodiment of the invention.

FIG. 2 illustrates operations of the pellicle film transfer apparatus as illustrated in FIG. 1.

### DETAILED DESCRIPTION

Referring to the drawings, an embodiment of the invention will be described below.

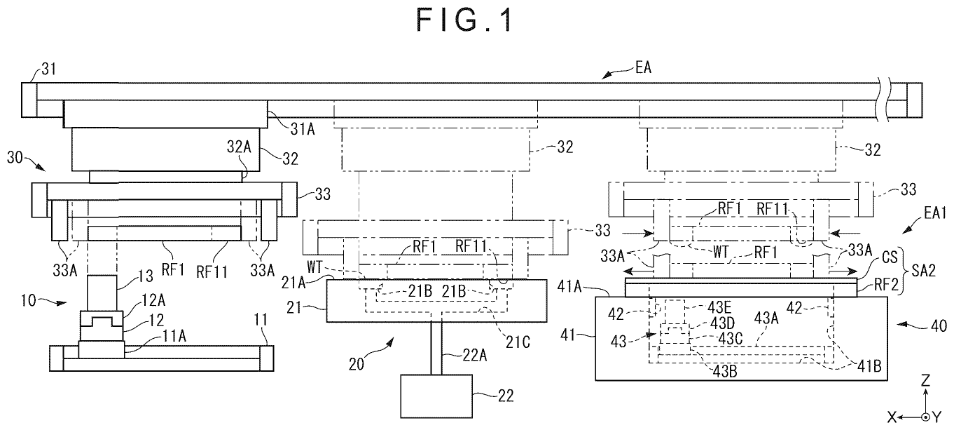

An X-axis, a Y-axis, and a Z-axis in the exemplary embodiment are orthogonal to each other, in which the X-axis and the Y-axis are defined as axes in a predetermined plane and the Z-axis is defined as an axis perpendicular to the predetermined plane. In the exemplary embodiment, in a case where directions are defined as viewed from a near direction in FIG. 1 parallel to the Y-axis as a reference, “up” corresponds to an arrow direction of the Z-axis and “down” is the opposite direction thereto, “left” is an arrow direction of the X-axis and “right” is the opposite direction thereto, and “front” is the near direction in FIG. 1 parallel to the Y-axis and “rear” is the opposite direction thereto.

A pellicle film attachment device EA includes an affinity improvement treatment unit 10, a liquid adhesion unit 20, and an attachment unit 30. The affinity improvement treatment unit 10 performs an affinity improvement treatment step of performing, on an adherend surface RF11 of a first frame member RF1, an affinity improvement treatment to improve an affinity for water WT as a liquid selected from water WT, one or more low-molecular-weight alcohols, or a combination thereof. The liquid adhesion unit 20 performs a liquid adhesion step of causing the exemplary water WT to adhere to the adherend surface RF11 having been subjected to the affinity improvement treatment. The attachment unit 30 performs an attachment step of attaching a pellicle film CS to the adherend surface RF11 to which the water WT adheres.

It is preferred that the affinity for the liquid refers to a property in which the adherend surface RF11 for the liquid to adhere to is easily wet with the liquid and the liquid easily, preferably evenly, spreads over the adherend surface RF11. It is preferred that the affinity improvement treatment refers to a treatment by which a contact angle of the liquid to the adherend surface RF11 after the affinity improvement treatment is lower than that before the affinity improvement treatment.

In the exemplary embodiment, the first frame member RF1 and a second frame member RF2 each include an annular metal member having a central opening, and the pellicle film CS is sized to span the opening of each of the frame members RF1 and RF2. The pellicle film CS of the exemplary embodiment is in a form of a sheet including carbon nanotubes. A surface of the pellicle film CS (the bottom surface facing downward) is attached to the second frame member RF2 to form an attachment body SA2 for a subsequent pellicle film CS transfer.

A pellicle film transfer apparatus EA1 includes the pellicle film attachment device EA and a transfer unit 40 that performs a transfer step of transferring the pellicle film CS attached to the second frame member RF2 to the first frame member RF1.

The affinity improvement treatment unit 10 includes a linear motor 11 serving as drive equipment, a linear motor 12 serving as drive equipment supported by a slider 11A of the linear motor 11, and a plasma irradiator 13 serving as an irradiation unit supported by a slider 12A of the linear motor 12. The linear motor 11 moves the plasma irradiator 13 in the left-right direction. The linear motor 12 moves the plasma irradiator 13 in the front-rear direction.

The liquid adhesion unit 20 includes a table 21 and a liquid supply unit 22, such as a pressure pump or a turbine, that supplies the liquid or exemplary water WT to the table 21.

The table 21 has a support surface 21A (a.k.a., a top facing up X-Y planar surface of the table 21) and a flow path 21C. The support surface 21A is provided with liquid supply ports 21B to which the water WT is supplied for wetting the support surface 21A (or wetting subsequently a downward-facing surface of the first frame member RF1). The flow path 21C is connected to the liquid supply unit 22 through a pipe 22A and communicates with the liquid supply ports 21B.

The attachment unit 30 includes a linear motor 31 serving as drive equipment, a linear motion motor 32 serving as drive equipment supported by a slider 31A of the linear motor 31, and a chuck cylinder 33 serving as a holder supported by an output shaft 32A of the linear motion motor 32 and including a plurality of holding members 33A to hold the first frame member RF1. The linear motor 31 moves the chuck cylinder 33 in the left-right direction. The linear motion motor 32 moves the chuck cylinder 33 in the up-down direction.

The transfer unit 40 includes a table 41 that supports the attachment body SA2, a heating unit 42, such as a coil heater or a heating side of a heat pipe, serving as a dryer that dries the pellicle film CS, and a cutter unit 43 that cuts the pellicle film CS.

The table 41 has a support surface 41A and a recess 41B. The support surface 41A is a surface on which a lower surface of the attachment body SA2 can be retained by suction with a non-illustrated decompression unit (retainer) such as a decompression pump or a vacuum ejector. The recess 41B is formed in the support surface 41A.

The heating unit 42 is in an annular shape along a side surface of the recess 41B, and is supported by the side surface.

The cutter unit 43 includes a linear motor 43A serving as drive equipment configured on a bottom surface of the recess 41B, a linear motor 43C serving as drive equipment supported by a slider 43B of the linear motor 43A, and a laser cutter 43E supported by a slider 43D of the linear motor 43C. The linear motor 43A moves the laser cutter 43E in the left-right direction. The linear motor 43C moves the laser cutter 43E in the front-rear direction.

A description will be made on operation of the pellicle film transfer apparatus EA1 including the above pellicle film attachment device EA.

First, a user of the pellicle film transfer apparatus EA1 (hereinafter, referred to simply as “user”) inputs, via a non-illustrated operation unit such as an operation panel or a personal computer, a signal for starting automatic operation to the pellicle film transfer apparatus EA1, and placing the components of the pellicle film transfer apparatus EA1 at respective initial positions illustrated by solid lines in FIG. 1. Subsequently, the user or a non-illustrated conveyance unit such as an articulated robot or a belt conveyor puts the attachment body SA2 on the support surface 41A. The transfer unit 40 then drives a non-illustrated decompression unit to start retaining the lower surface of the attachment body SA2 by suction on the support surface 41A, as illustrated in FIG. 1 Right.

After that, the user or non-illustrated conveyance unit places the first frame member RF1 in between the plurality of holding members 33A, as illustrated in FIG. 1 Left, according to one embodiment. The attachment unit 30 then drives the chuck cylinder 33 to cause the first frame member RF1 to be held by the holding members 33A, as illustrated by two-dot chain lines in FIG. 1 Left. Subsequently, the affinity improvement treatment unit 10 provides the affinity improvement treatment by driving the linear motors 11 and 12 to move the plasma irradiator 13 around 360 degrees along the adherend surface RF11 of the first frame member RF1 and irradiating the adherend surface RF11 with plasma. Accordingly, the affinity of the adherend surface RF11 is improved and the surface is cleaned.

As illustrated in FIG. 1 Center, the liquid adhesion unit 20 then drives the liquid supply unit 22 to supply the water WT to the liquid supply ports 21B. Subsequently, the attachment unit 30 drives the linear motor 31 and the linear motion motor 32 to move the first frame member RF1 rightward and then downward, causing the water WT supplied to the liquid supply ports 21B to adhere to the adherend surface RF11 of the first frame member RF1, as illustrated by two-dot chain lines in FIG. 1 Center. At this time, the water WT is spread (or applied) evenly on(to) the affinity improvement treatment-treated adherend surface RF11.

After that, the attachment unit 30 drives the linear motor 31 and the linear motion motor 32 to move the first frame member RF1 upward and then rightward, causing the first frame member RF1 to be positioned above the pellicle film CS. Next, the attachment unit 30 drives the chuck cylinder 33 to bring the holding members 33A close to each other to compress the first frame member RF1 inward, as illustrated by the two-dot chain lines in FIG. 1 Right. The attachment unit 30 then drives the linear motion motor 32 to move the first frame member RF1 downward as illustrated by the two-dot chain lines in FIG. 1, causing the water WT adhering to the adherend surface RF11 to come into contact with the other of the surfaces of the pellicle film CS (top surface facing up). The pellicle film CS is thus attached to the adherend surface RF11 with the water WT. Subsequently, the transfer unit 40 configures the heating unit 42 to dry the pellicle film CS by heating, and then the attachment unit 30 drives the chuck cylinder 33 so that the holding members 33A move outward to release the compression of the first frame member RF1. Tension of the pellicle film CS is thus increased. After that, the linear motors 43A and 43C are configured to move the laser cutter 43E along the outer circumference of the adherend surface RF11 to cut the pellicle film CS, so that the pellicle film CS is divided into a pellicle film CS1 attached to the first frame member RF1 and an unnecessary sheet US attached to the second frame member RF2.

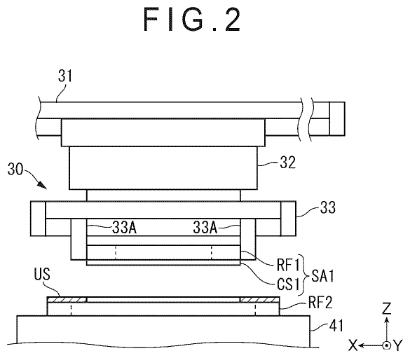

Next, the attachment unit 30 drives the linear motion motor 32 to move the first frame member RF1 upward as illustrated in FIG. 2, thus separating the pellicle film CS1 in the predetermined shape from the second frame member RF2. Accordingly, the pellicle film CS is transferred to the first frame member RF1, providing an attachment body SA1 with the pellicle film CS1 attached to the first frame member RF1. The user or the non-illustrated conveyance unit then conveys the attachment body SA1 to a next step and conveys the second frame member RF2 attached with the unnecessary sheet US of the pellicle film CS (i.e., a remaining portion of the pellicle film CS attached to the second frame member RF2) to a collection unit such as a box or a cassette. Thereafter, the same operation as above is repeated.

According to the exemplary embodiment as above, the adherend surface RF11 of the first frame member RF1 is subjected to the affinity improvement treatment. The water WT thus evenly adheres to the adherend surface RF11, which renders a capability of preventing the pellicle film CS from being unevenly attached to the adherend surface RF11 of the first frame member RF1, resulting in folding a portion of the pellicle film CS1 and altering light transmittance evenness across the pellicle film CS1 (i.e., changes of the pellicle film CS1 density and porosity).

The best configuration, method, and the like for carrying out the invention are disclosed in the above description. The invention, however, is not limited thereto. Thus, although the invention is particularly illustrated and described primarily with respect to a specific exemplary embodiment, those skilled in the art may make various modifications to the above exemplary embodiment in terms of shape, material, numerical quantity, and other detailed configurations without departing from the technical idea and the scope of the object of the invention. Further, the descriptions limiting the shapes, materials, and the like disclosed hereinabove are given as examples to facilitate understanding of the invention, and are not intended to limit the invention. Therefore, descriptions in which components are named without some or all of the limitations on shape, material, and the like are within the scope of the invention.

Moreover, the units and steps in the invention are by no means limited as long as the operation, functions, or steps described in connection with the units and steps are achievable, and are in no way limited to the merely exemplary components or steps described in the above exemplary embodiment. For instance, the transfer unit may be any unit capable of transferring the pellicle film attached to the second frame member to the first frame member, and is by no means limited insofar as being, in light of common technical knowledge in the art at the time of the filing the present application, within a technical scope of the knowledge (the same applies to any other units and steps).

The affinity improvement treatment unit 10 may perform the affinity improvement treatment on the adherend surface RF11 of the first frame member RF1 before the first frame member RF1 is held by the chuck cylinder 33, may perform the affinity improvement treatment on a plurality of first frame members RF1 at once, and may cause the adherend surface RF11 to face the water WT after performing the affinity improvement treatment in a state where the adherend surface RF11 faces up or aside.

In another instance, the affinity improvement treatment unit 10 may perform the affinity improvement treatment by irradiating the adherend surface RF11 with an energy beam, such as an electron beam or a microwave, using an irradiation unit, such as an electron beam irradiator or a microwave irradiator, heating or cooling the adherend surface RF11, or applying a chemical to the adherend surface RF11. Any approach is usable with the characteristics, qualities, properties, materials, compositions, configurations, and the like of the first frame member RF1 and the adherend surface RF11 taken into consideration, insofar as the affinity improvement treatment can be performed on adherend surface RF11.

The liquid adhesion unit 20 may be configured to cause liquid to adhere to the adherend surface RF11 of the first frame member RF1, e.g. spraying.

Regarding the liquid to be configured to adhere to the adherend surface RF11, any liquid is usable with the characteristics, qualities, properties, materials, compositions, configurations, and the like of the first frame member RF1 and the adherend surface RF11 and the characteristics, qualities, properties, materials, compositions, configurations, and the like of pellicle film CS taken into consideration, insofar as the liquid enables the pellicle film CS to be attached to the adherend surface RF11. For instance, the liquid may be a polar solvent such as a low-molecular alcohol (e.g., isopropyl alcohol, methanol, and ethanol), a mixed solvent of the water WT, and the like. In particular, in terms of letting no material other than the pellicle film CS remain on the adherend surface RF11, the liquid preferably consists of a component evaporable or volatilizable by heat or air drying, and the liquid is preferably the water WT, an organic solvent, or a mixed solvent thereof.

Adopting this approach avoids a common practice of applying an adhesive to attaching one object to another, especially concerning a nanotube pellicle film for EUV lithography application. Adhesives or even residues of any adhesives may introduce undesirable volatile organic chemicals, contaminants, or particles to an ultra-clean semiconductor production environment, especially inside an EUV lithography scanner. Removing adhesive by any means may cause damage to the pellicle film CS or introduce adhesive-derived molecules to be deposited onto the surfaces of the pellicle film CS.

The attachment unit 30 may hold the first frame member RF1 with a plurality of chuck cylinders 33. The attachment unit 30 may or may not compress the first frame member RF1.

The holder may hold the first frame member RF1 with drive equipment such as an articulated robot, a robotic arm, a mechanical chuck, or an actuator. The attachment unit 30 may include, in place of or in combination with the holder, a retainer that retains the first frame member RF1 by suction or with an adhesive or the like.

The transfer unit 40 may include no heating unit 42. The transfer unit 40 may cause the adherend surface RF11 of the first frame member RF1 to be attached to one of the surfaces of the pellicle film CS. The transfer unit 40 may omit the cutter unit 43. The transfer unit 40 may be used not in combination with the attachment unit 30. In a case where the transfer unit 40 includes no cutter unit 43, the pellicle film CS may be separated from the second frame member RF2 without cutting the pellicle film CS. In a case where the transfer unit 40 includes no cutter unit 43 or is not used in combination with the attachment unit 30, another device may be used to separate the pellicle film CS from the second frame member RF2.

The dryer may include a spraying unit, such as a spraying tube or a nozzle, through which a heated gas, including, but not limited to, air and inert gas, or the like heated by the heating unit 42 or alike is applied onto the pellicle film CS, preferably a portion of the pellicle film CS overlaying the surface of the first frame member RF1.

The frame members RF1 and RF2 may be formed, for instance, from metal such as stainless steel, aluminum, copper, or brass, resin such as silicone, fluorine resin, or acrylic resin, or a ceramic material. Silicon or quartz with a low thermal expansion coefficient is preferred. Silicon that is easy to be machined into a desired shape is more preferably used. The shape may be a non-annular shape (a shape having a discontinuous circumference), a circle, an oval, a polygon, or any other shape.

The material, type, shape, and the like of the pellicle film CS and the frame members RF1 and RF2 in the invention are not particularly limited. For instance, the pellicle film CS and the frame members RF1, RF2 may be in a shape of a circle, an oval, or a polygon such as a triangle, a quadrangle, or in any other shape.

Regarding the drive equipment of the above exemplary embodiment, motorized equipment such as a rotary motor, a linear motion motor, a linear motor, a single-axis robot, or a so-called articulated robot having biaxial or tri- or more axial joints, an actuator such as an air cylinder, a hydraulic cylinder, a rodless cylinder, or a rotary cylinder, and the like, may be used alone, or provided by a direct or indirect combination. Or, one capable or incapable of performing a torque control, a speed control, or the like on an output section of the motorized equipment, the actuator, or the like may be used.

In the above exemplary embodiment, an object (hereinafter, referred to as “object A”) and another object (hereinafter, referred to as “object B”) movable with respect to the object A, that is, relatively movable object A and object B may be defined as follows. The object B may be moved with respect to the immovable object A, the object A may be moved with respect to the immovable object B, or both the object A and the object B may be moved. It does not matter which one of the object A and the object B is to be moved insofar as the movement achieves the same result. In a case where there is provided an element, such as a support (retaining) unit or a support (retaining) member, that supports (retains) a member to be supported (a member to be retained), the member to be supported may be supported (retained) by a holder such as a mechanical chuck or a chuck cylinder, Coulomb force, an adhesive (an adhesive sheet or an adhesive tape), a sticky agent (a sticky sheet or a sticky tape), magnetic force, Bernoulli suction, suction adsorption, drive equipment, or the like. In a case where there is provided an element, such as a cutter unit or a cutting member, that cuts a member to be cut or makes a cut or a cut line in the member to be cut, the cutting may be performed with, in place of or in combination with the above exemplary element, a cutter blade, a laser cutter, ion beam, electric discharge machining, firepower, heat, hydraulic pressure, heating wire, or an element that performs cutting by spraying or the like of a gas, a liquid, or the like. Or, the cutting may be performed by moving the object to be cut by a combination of appropriate drive equipment.

What is claimed is:

1. A pellicle film attachment device comprising:
an affinity improvement treatment unit configured to perform, on an adherend surface of a first frame member, an affinity improvement treatment to improve an affinity for a liquid;
a liquid adhesion unit configured to cause the liquid to adhere to the adherend surface having been subjected to the affinity improvement treatment; and
an attachment unit configured to attach a pellicle film to the adherend surface to which the liquid adheres.

2. A pellicle film transfer apparatus comprising:
the pellicle film attachment device according to claim 1; and
a transfer unit configured to transfer the pellicle film attached to a second frame member to the first frame member.

3. A pellicle film attachment method comprising:
performing, on an adherend surface of a first frame member, an affinity improvement treatment to improve an affinity for a liquid;
causing the liquid to adhere to the adherend surface having been subjected to the affinity improvement treatment; and
attaching a pellicle film to the adherend surface to which the liquid adheres.

4. A pellicle film transfer method comprising:
the pellicle film attachment method according to claim 3; and
transferring the pellicle film attached to a second frame member to the first frame member.
